(19) United States
(12) Patent Application Publication
(10) Pub. No.: US 2026/0216739 A1
(43) Pub. Date: Jul. 30, 2026

(54) ANTI-BACKFLOW APPARATUS AND SUBSTRATE PROCESSING DEVICE

(71) Applicant: ACM RESEARCH (SHANGHAI), INC., Shanghai (CN)

(72) Inventors: Jian Chen, Shanghai (CN); Qi Li, Shanghai (CN); Jianjun Ding, Shanghai (CN); Xiaoyan Zhang, Shanghai (CN); Zhenming Chu, Shanghai (CN); Junyan Zuo, Shanghai (CN); Shena Jia, Shanghai (CN); Jinzhao Dai, Shanghai (CN)

(73) Assignee: ACM RESEARCH (SHANGHAI), INC., Shanghai (CN)

(21) Appl. No.: 19/144,746

(22) PCT Filed: Dec. 13, 2023
(86) PCT No.: PCT/CN2023/138382

§ 371 Date: Jun. 30, 2025

(30) Foreign Application Priority Data
Dec. 30, 2022 (CN) 202211720563.9

(51) Int. Cl. B05B 1/30

(52) U.S. Cl. CPC B05B 1/3013

(57) ABSTRACT

An anti-backflow apparatus includes a cup, a protective cover, and a gas exhaust unit. The upper portion of the cup is provided with an opening. The protective cover covers the opening of the cup and is provided with a liquid receiving port and a gas exhaust port. The liquid receiving port is used for a nozzle to drip chemical liquid into the cup. The gas exhaust unit is connected to the inside of the cup through the gas exhaust port of the protective cover, so as to suck volatile gas inside the cup, which can effectively prevent the volatile gas inside the cup from flowing back into a process chamber of a substrate processing device, and can prevent the volatile gas from corroding the surface of a substrate in the process chamber.

### FIELD OF THE INVENTION

The present invention relates to the field of semiconductor manufacturing, and in particular to an anti-backflow apparatus and a substrate processing device.

### BACKGROUND

During the operation of a cleaning device, a nozzle in a process chamber supplies chemical liquid to the surface of a rotating substrate, and the purpose of cleaning the substrate is achieved by using different concentrations and dosages of chemical liquid on the substrate to corrode and clean adherent particles on the surface of the substrate, so as to ensure the cleanliness of the substrate. Usually, before the nozzle supplies the chemical liquid to the substrate, it is pre-flushed above a cup, that is, the chemical liquid at the position of liquid outlet of the nozzle is dripped into the cup to ensure that the chemical liquid supplied by the nozzle to the substrate is fresh and clean. When the cleaning device is not working for a long time, the nozzle will automatically flush above the cup, that is, the chemical liquid at the position of liquid outlet of the nozzle will be dripped into the cup at regular intervals, so as to keep the chemical liquid in the nozzle fresh and clean.

The cup has the shape of a cup body whose upper portion is completely open, and the chemical liquid in the nozzle is, for example, the high-concentration acid or alkali liquid. On the one hand, due to the inherent volatilization phenomenon of high-concentration acid or alkali liquid, a large amount of volatilized gas such as acid mist or acid gas from the chemical liquid will volatilize from the completely open opening of the cup into the process chamber of the cleaning device, polluting the process environment in the process chamber. When the substrate is rotated and the chemical liquid is spun dry, the first exposed area is adhered to the acid gas. On the other hand, in order to prevent the toxic gas inside the process chamber from flowing into the outside and causing harm to people, the toxic gas inside the process chamber is usually sucked by the Box Exhaust System of the cleaning device, which causes the inside of the process chamber to become a negative pressure atmosphere. And when the chemical liquid inside the cup needs to be recovered, the liquid discharge pipeline of the cup is connected to the Chemical Distribution System (CDS), so that the chemical liquid inside the cup, such as N-methylpyrrolidone (NMP), is recovered to the CDS for recovery processing. Therefore, the volatile gas, such as NMP gas, accumulated at the position of liquid discharge pipeline of the cup is easily flowed back into the inside of the process chamber under negative pressure through the cup, resulting in the adhesion of NMP gas on the surface of the substrate, especially in the central area of the substrate. Depending on the different types of chemical liquid, there will be different areas and degrees of volatile gases adhering to the surface of the substrate, which leads to the production of harmful corrosion and greatly reduces the yield of the substrate during the actual cleaning process.

### SUMMARY

The present invention aims to solve the problem that a large amount of volatile gas inside the cup flows back into the process chamber and corrodes the surface of the substrate in the prior art. Therefore, the present invention provides an anti-backflow apparatus and a substrate processing device, which have the advantages that the gas in the anti-backflow apparatus is discharged from the process chamber and the gas is prevented from flowing back into the process chamber.

In order to solve the above problem, an embodiment of the present invention provides an anti-backflow apparatus, comprising:
a cup, having an opening on an upper portion of the cup;
a protective cover, covering the opening of the cup, and being provided with a liquid receiving port and a gas exhaust port, the liquid receiving port being used for a nozzle to drip chemical liquid into the cup; and
a gas exhaust unit, connected to the inside of the cup through the gas exhaust port of the protective cover, so as to suck volatile gas inside the cup.

Another embodiment of the present invention provides a substrate processing device, comprising:
a process chamber;
a substrate chuck, arranged inside the process chamber, for carrying a substrate;
a nozzle, for supplying chemical liquid to the substrate; and
an anti-backflow apparatus described above, the anti-backflow apparatus and the nozzle being both arranged inside the process chamber.

Compared with the prior art, the present invention has the following beneficial effects:

The anti-backflow apparatus of the present invention is provided with a protective cover on the cup, and a liquid receiving port and a gas exhaust port are provided on the protective cover. The nozzle drips the chemical liquid into the cup through the liquid receiving port, and the gas inside the cup is discharged from the gas exhaust port of the protective cover through the gas exhaust unit, so as to effectively prevent the gas inside the cup from flowing back into the process environment around the cup.

The substrate processing device of the present invention adopts the anti-backflow apparatus described above, so that the gas inside the cup is discharged from the process chamber through the gas exhaust port of the protective cover by the gas exhaust unit, and the volatile gas inside the cup is prevented from flowing back to the inside of the process chamber, thereby preventing the backflow gas from corroding the surface of the substrate in the process chamber.

Other features and corresponding benefits of the present invention are set forth later in the specification, and it is to be understood that at least some of the beneficial effects will become apparent from the description in the specification of the present invention.

### BRIEF DESCRIPTION OF THE DRAWINGS

FIG. 1 is a schematic view illustrating a working principle of a substrate processing device provided in embodiment 1 of the present invention;

FIG. 2 is an exploded schematic view of an anti-backflow apparatus provided in embodiment 1 of the present invention;

FIG. 3 is a perspective schematic view of an anti-backflow apparatus provided in embodiment 1 of the present invention; and

FIG. 4 is a perspective schematic view of an anti-backflow apparatus provided in embodiment 2 of the present invention.

### PREFERRED EMBODIMENTS OF THE INVENTION

Hereinafter, the embodiments of the present invention will be described with reference to specific embodiments, and other advantages and effects of the present invention will be readily apparent to those skilled in the art from the disclosure of the present specification. Although the description of the present invention will be described in conjunction with preferred embodiments, this does not mean that the features of the present invention are limited to this embodiment. On the contrary, the purpose of the description in connection with the embodiments is to cover other alternatives or modifications that may be extended based on the claims of the present invention. In order to provide an in-depth understanding of the present invention, many specific details will be included in the following description. The present invention may also be practiced without these details. Furthermore, in order to avoid confusion or obscuring the focus of the present invention, some specific details will be omitted in the description. It should be noted that the embodiments of the present invention and the features of the embodiments may be combined with each other as long as there is no conflict.

It should be noted that in the present specification, similar reference numerals and letters refer to similar items in the following drawings, and thus, once an item is defined in one drawing, it is not necessary to further define and explain the item in the following drawings.

Hereinafter, the technical solutions of the present invention will be clearly and completely described with reference to the accompanying drawings, and it is obvious that the described embodiments are some embodiments of the present invention, but not all embodiments. Based on the embodiments in the present invention, all other embodiments obtained by those of ordinary skill in the art without making creative efforts belong to the scope of protection of the present invention.

In the description of the present invention, it should be noted that the orientation or positional relationship indicated by the terms “center”, “upper”, “lower”, “left”, “right”, “vertical”, “horizontal”, “inner”, “outer”, etc., is based on the orientation or positional relationship shown in the accompanying drawings. It is only for convenience and simplification of the description of the present invention, and does not indicate or imply that the referred device or element must have a specific orientation, be constructed and operate in a specific orientation, and therefore cannot be understood as a limitation of the present invention. Furthermore, the terms “first”, “second” and “third” are for descriptive purposes only and cannot be understood as indicating or implying relative importance.

In the description of the present invention, it should be noted that unless otherwise explicitly specified and defined, the terms “mounted”, “connected” and “communicated” should be understood in a broad sense, for example, may be fixed connection, may be detachable connection, or may be integral connection; The connection may be mechanical connection or electrical connection; It may be direct connection, indirect connection through an intermediate medium, and it can be the internal communication of two elements. The specific meanings of the above terms in the present invention will be understood by those of ordinary skill in the art.

In order to clarify the objects, technical solutions and advantages of the present invention, the embodiments of the present invention will be described in further details below with reference to the accompanying drawings.

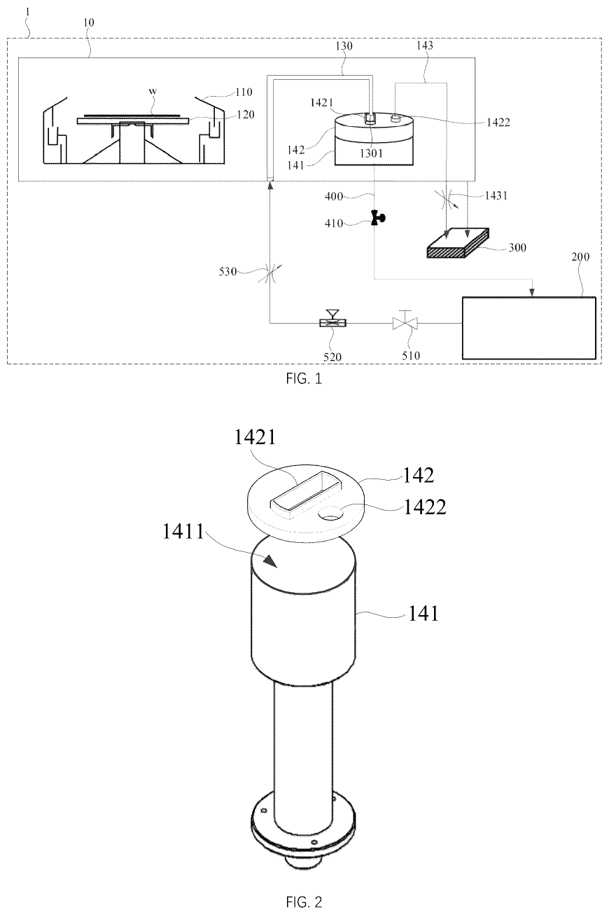

Referring to FIG. 1, the substrate processing device 1 according to the present invention comprises a process chamber 10, a substrate chuck 120, a nozzle 130 and an anti-backflow apparatus. The inside of the process chamber 10 is also provided with a reaction chamber 110, the reaction chamber 110 has a cup shape, and the upper portion of the reaction chamber 110 is open. The substrate chuck 120 is provided inside the reaction chamber 110 and is used to carry the substrate w. In other alternative embodiments, the reaction chamber 110 may also have a square shape or other structure, and the shape of the reaction chamber 110 is not limited in this application.

Both the nozzle 130 and the anti-backflow apparatus are provided inside the process chamber 10, and both are located outside the reaction chamber 110. When the nozzle 130 is working, the chemical liquid is supplied to the substrate w through the upper opening of the reaction chamber 110. When the nozzle 130 is not working, that is, when the nozzle 130 finishes supplying the chemical liquid to the substrate w, the nozzle 130 moves to the position of the anti-backflow apparatus to perform flush, for example, preflush or autoflush, ensuring that the chemical liquid in the nozzle 130 is always clean.

The chemical liquid sprayed onto the substrate w by the nozzle 130 is, for example, the acid chemical liquid, the alkali chemical liquid, the organic chemical liquid, the rinsing liquid, or the like. The acid chemical liquid is, for example, DHF (dilute hydrofluoric acid) or the like, the alkali chemical liquid is, for example, SC1 (a mixture of ammonia water, hydrogen peroxide and water) or the like, the organic chemical liquid is, for example, IPA (isopropanol) or the like, and the rinsing liquid is, for example, DIW (deionized water) or the like.

In conjunction with FIGS. 1 to 3, the anti-backflow apparatus proposed by the present invention comprises a cup 141, a protective cover 142 and a gas exhaust unit. The cup 141 has an opening 1411, and the protective cover 142 covers the opening 1411 of the cup 141 and is provided with a liquid receiving port 1421 and a gas exhaust port 1422. When the nozzle 130 is not working, the chemical liquid is dripped into the cup 141 through the liquid receiving port 1421. The gas exhaust unit comprises a negative pressure pipeline 143 and a gas exhaust device 300. A first end of the negative pressure pipeline 143 communicates with the inside of the cup 141 through the gas exhaust port 1422 of the protective cover 142. A second end of the negative pressure pipeline 143 is connected to the gas exhaust device 300. When the nozzle 130 is flushed or not, the gas exhaust device 300 continuously sucks the volatile gas inside the cup 141 through the negative pressure pipeline 143, so that the volatile gas of the chemical liquid inside the cup 141, such as the acid mist or acid gas, is continuously discharged from the process chamber 10.

In the present embodiment, the gas exhaust device 300 may adopt a Box Exhaust System conventionally used in the substrate processing device 1, and the Box Exhaust System is usually used to suck the gas inside the process chamber 10. In this embodiment, the gas exhaust device 300 and the cup 141 are connected through a negative pressure pipeline 143, so that the cup 141 and the process chamber 10 share one gas exhaust device 300. The gas exhaust device 300 not only sucks the gas inside the process chamber 10, but also continuously sucks the volatile gas inside the cup 141 through the negative pressure pipeline 143, effectively prevents the volatile gas inside the cup 141 from flowing back into the process chamber 10 without affecting the flush of the nozzle 130 at the same time, and prevents the backflow gas from contaminating the process environment inside the process chamber 10 and causing undesirable corrosion on the surface of the substrate w. Wherein, the negative pressure pipeline 143 may be made of PFA (Polyfluoroalkoxy) material, the negative pressure pipeline 143 is fixed to the process chamber 10 through a fixing plate 1431, and a regulating valve 1431 may be provided on the negative pressure pipeline 143 to regulate the flow rate of the gas in the negative pressure pipeline 143. The regulating valve 1431 is, for example, a Needle Valve (NV).

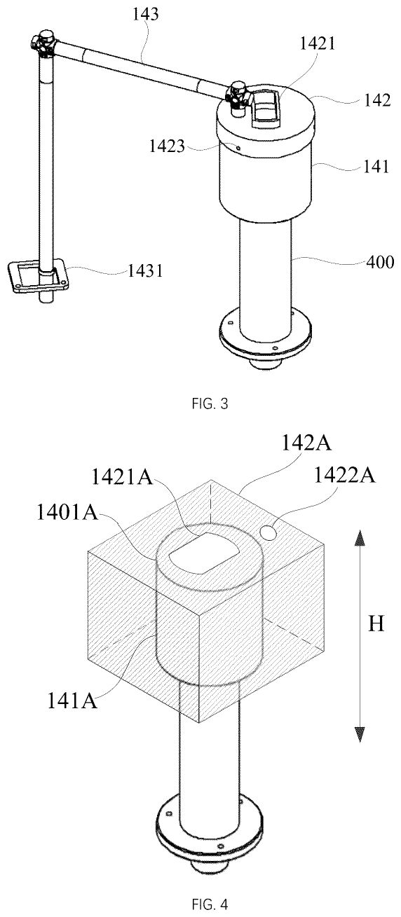

As shown in FIG. 3, the protective cover 142 of the anti-backflow apparatus covers the upper portion of the cup 141, and the liquid receiving port 1421 and the gas exhaust port 1422 are both provided on the top wall of the protective cover 142. In the present embodiment, the protective cover 142 half covers the upper portion of the cup 141, corresponding to the upper lid of the cup 141. The protective cover 142 is transitionally matched with the cup 141 to ensure the basic positioning of the protective cover 142. The side wall of the protective cover 142 is fixed to the side wall of the cup 141 by a fastener 1423. Wherein, the fastener 1423 comprises three anti-corrosion bolts, and the three anti-corrosion bolts are evenly distributed along the outer periphery of the protective cover 142 to fix the protective cover 142 and the cup 141 at a distribution angle of 120°.

In conjunction with FIGS. 1 and 3, the liquid receiving port 1421 protrudes from the top wall of the protective cover 142 and extends outward, and the upper surface of the liquid receiving port 1421 is not higher than the liquid outlet surface 1301 of the nozzle 130, so as to prevent the nozzle 130 from interfering with the liquid receiving port 1421 and colliding with each other when rotating between the cup 141 and the substrate w. When the liquid receiving port 1421 and the liquid outlet of the nozzle 130 do not interfere with each other, the liquid receiving port 1421 should be brought close to the liquid outlet of the nozzle 130 as much as possible, so as to prevent the chemical liquid from splashing out of the liquid receiving port 1421 when the nozzle 130 drips the liquid into the cup 141.

As shown in FIG. 2, the area of the liquid receiving port 1421 of the protective cover 142 does not exceed ⅓ of the area of the opening 1411 of the cup 141, preventing the acid mist or acid gas from overflowing due to excessive size of the liquid receiving port 1421. The size of the liquid receiving port 1421 should not be too small, and the size of the liquid receiving port 1421 should be at least larger than the size of the liquid outlet of the nozzle 130, ensuring that the nozzle 130 can smoothly flush the cup 141, such as preflush or autoflush.

In conjunction with FIGS. 1 and 3, the anti-backflow apparatus further comprises a liquid discharge pipeline 400, and the liquid discharge pipeline 400 is provided at a lower portion of the cup 141. Usually, if the chemical liquid in the cup 141 does not need to be recovered, the liquid discharge pipeline 400 is connected to the factory service system, so that the chemical liquid in the cup 141 is directly discharged to the factory service system. When the chemical liquid in the cup 141 needs to be recovered, the liquid discharge pipeline 400 is connected to the recovery processing unit 200, so that the chemical liquid in the cup 141 passes through the recovery processing unit 200, and the recovery processing unit 200 supplies the processed chemical liquid to the nozzle 130. The chemical liquid supply pipeline between the nozzle 130 and the recovery processing unit 200 comprises a Manual Valve (MV) 510, a Pressure Control Valve (PCV) 520 and a Needle Valve (NV) 530. The Manual Valve 510 is used to control the on-off of the chemical liquid supply pipeline, the Pressure Control Valve 520 is used to control the pressure of the supply pipeline, and the Needle Valve 530 is used to control the flow rate of the chemical liquid of the supply pipeline.

In the present embodiment, the recovery processing unit 200 may adopt a Chemical Distribution System (CDS) existing in the substrate processing device 1, and the Chemical Distribution System has a gas exhaust portion communicating with the gas exhaust portion of the factory service system, for exhausting the gas in the Chemical Distribution System. The liquid discharge pipeline 400 is provided with a control valve 410, which may be a pneumatic valve. When the nozzle 130 is flushed, that is, during the period of the nozzle 130 drips the chemical liquid into the cup 141 through the liquid receiving port 1421, the pneumatic valve is opened, so that the chemical liquid in the cup 141 is introduced into the Chemical Distribution System through the liquid discharge pipeline 400. The chemical liquid in the nozzle 130, for example, is the N-methylpyrrolidone (NMP) chemical liquid; When the nozzle 130 finishes flushing, that is, when the nozzle 130 finishes dripping the chemical liquid into the cup 141, the nozzle 130 moves above the substrate w and supplies the chemical liquid to the substrate w. At this time, the pneumatic valve is closed to prevent the gas from the Chemical Distribution System from flowing back into the process chamber 10 through the liquid discharge pipeline 400 and the cup 141. Since the gas exhaust device 300 continuously sucks the inside of the cup 141 through the negative pressure pipeline 143, hence, when the pneumatic valve changes from closed to open, after the volatile gas accumulated in the liquid discharge pipeline 400 enters the inside of the cup 141, the volatile gas will be sucked away by the Box Exhaust System through the negative pressure pipeline 143, thereby effectively preventing the volatile gas accumulated in the liquid discharge pipeline 400 from flowing back into the process chamber 10 through the inside of the cup 141, and avoiding the surface of the substrate w from being adhered and corroded by the volatile gas.

### Second Embodiment

Referring to FIG. 4, the second embodiment provides another anti-backflow apparatus, which is different from the first embodiment in that:

The protective cover 142A of the anti-backflow apparatus may also cover the outer periphery of the cup 141A and form a cavity between the protective cover 142A and the outer periphery of the cup 141A. The liquid receiving port 1421A is provided on the top wall of the protective cover 142A, and the gas exhaust port 1422A is provided on the side wall of the protective cover 142A. In the present embodiment, the protective cover 142A completely covers the outer periphery of the cup 141A, corresponding to a sealing cover of the cup 141A, and is fixed to the outer periphery of the cup 141A. The protective cover 142A and the cup 141A may be integrally formed by welding. In other alternative embodiments, the protective cover 142A may be half covered on the outer periphery of the cup 141A, that is, covering the opening and a part of the side wall of the cup 141A, and a cavity is formed between the protective cover 142A and the opening and a part of the side wall of the cup 141A. The protective cover 142 A may also be sleeved outside the cup 141 A and fixed to the inside of the process chamber by a supporter (not shown in the picture). Herein, it should be noted that a seal may be provided at a position where the protective cover 142A comes into contact with the outside of the cup 141A, so as to prevent the gas in the cavity between the protective cover 142A and the cup 141A from entering the inside of the process chamber.

Specifically, when a cavity is formed between the protective cover 142A and the outer periphery of the cup 141A, there is a buffer distance between the liquid receiving port 1421A of the protective cover 142A and the upper edge 1401A of the cup 141A. The buffer distance provides a buffer space for the volatile gas inside the cup 141A, so as to prevent the volatile gas inside the cup 141A from directly flowing back into the process chamber through the liquid receiving port 1421A.

Along the height direction H of the cup 141A, the position of the gas exhaust port 1422A of the protective cover 142A is not lower than the position along the upper edge 1401A on the cup 141A, and is used to timely discharge the gas in the cavity between the protective cover 142A and the cup 141A, especially the gas between the top wall of the protective cover 142A and the upper edge 1401A of the cup 141A.

Finally, it should be noted that the above embodiments are merely used to illustrate the technical solutions of the present invention, and are not intended to limit the present invention. Although the present invention has been described in detail with reference to the above-described embodiments, those of ordinary skill in the art should understand that the technical solutions described in the above-described embodiments may still be modified, or some or all of the technical features may be equivalently replaced. However, these modifications or substitutions do not cause the essence of the corresponding technical solutions to deviate from the scope of the technical solutions of each embodiment of the present invention.

1. An anti-backflow apparatus, comprising:
a cup, having an opening on an upper portion of the cup;
a protective cover, covering the opening of the cup, and being provided with a liquid receiving port and a gas exhaust port, the liquid receiving port being used for a nozzle to drip chemical liquid into the cup; and
a gas exhaust unit, connected to the inside of the cup through the gas exhaust port of the protective cover, so as to suck volatile gas inside the cup.

2. The anti-backflow apparatus according to claim 1, wherein the protective cover covers the upper portion of the cup, and the liquid receiving port and the gas exhaust port are both arranged on the top wall of the protective cover.

3. The anti-backflow apparatus according to claim 2, wherein the liquid receiving port protrudes from the top wall of the protective cover and extends outward.

4. The anti-backflow apparatus according to claim 2, wherein the side wall of the protective cover is fixed to the side wall of the cup by a fastener.

5. The anti-backflow apparatus according to claim 1, wherein the protective cover covers the outer periphery of the cup and forms a cavity between the protective cover and the outer periphery of the cup, the liquid receiving port is provided on the top wall of the protective cover, and the gas exhaust port is provided on the side wall of the protective cover.

6. The anti-backflow apparatus according to claim 5, wherein the protective cover is integrally formed with the cup.

7. The anti-backflow apparatus according to claim 5, wherein the gas exhaust port of the protective cover is not lower than the upper edge of the cup along the height direction of the cup.

8. The anti-backflow apparatus according to claim 1, wherein the area of the liquid receiving port does not exceed ⅓ of the area of the opening of the cup.

9. The anti-backflow apparatus according to claim 1, further comprising:
a liquid discharge pipeline, arranged at the lower portion of the cup, for discharging the chemical liquid from the inside of the cup;
a control valve, arranged on the liquid discharge pipeline, for opening or closing the liquid discharge pipeline;
wherein the control valve is opened during the period of the nozzle drips the chemical liquid into the cup through the liquid receiving port; the control valve is closed when the nozzle finishes dripping the chemical liquid into the cup.

10. The anti-backflow apparatus according to claim 9, further comprising:
a recovery processing unit, the liquid discharge pipeline and the nozzle being respectively connected to the recovery processing unit, the chemical liquid inside the cup being discharged to the recovery processing unit through the liquid discharge pipeline, and the recovery processing unit supplying the processed chemical liquid to the nozzle.

11. The anti-backflow apparatus according to claim 1, wherein the gas exhaust unit comprises a negative pressure pipeline and a gas exhaust device, and the gas exhaust device continuously sucks the volatile gas inside the cup through the negative pressure pipeline.

12. The anti-backflow apparatus according to claim 11, wherein the negative pressure pipeline is provided with a regulating valve, for regulating the flow rate of gas in the negative pressure pipeline.

13. A substrate processing device, comprising:
a process chamber;
a substrate chuck, arranged inside the process chamber, for carrying a substrate;
a nozzle, for supplying chemical liquid to the substrate; and
an anti-backflow apparatus according to claim 1, the anti-backflow apparatus and the nozzle being both arranged inside the process chamber.
